(19) United States
(12) Patent Application Publication
(10) Pub. No.: US 2014/0312923 A1
(43) Pub. Date: Oct. 23, 2014

(54) CONTACT INPUT APPARATUS SUPPORTING MULTIPLE VOLTAGE SPANS AND METHOD OF OPERATING THE SAME

(71) Applicant: GE INTELLIGENT PLATFORMS, INC., Charlottesville, VA (US)

(72) Inventor: Daniel ALLEY, Earlysville, VA (US)

(73) Assignee: GE Intelligent Platforms, Inc., Charlottesville, VA (US)

(21) Appl. No.: 13/864,333

(22) Filed: Apr. 17, 2013

(51) Int. Cl. G01R 19/00

(52) U.S. Cl. CPC G01R 19/0092
USPC 324/713

(57) ABSTRACT

A voltage from a switching device across a plurality of attenuation paths is received. Each of the attenuation paths provides a different attenuation to the voltage from the others. At embedded control logic, at least one of the plurality of attenuation paths is chosen and a sensed voltage is determined according to the at least one attenuation path that is chosen.

### CROSS REFERENCES TO RELATED APPLICATIONS

Utility application entitled “Apparatus and Method for Wetting Current Measurement and Control” naming as inventor Daniel Alley, and having attorney docket number 267012 (130838);

Utility application entitled “Programmable Contact Input Apparatus and Method of Operating the Same” naming as inventor Daniel Alley, and having attorney docket number 268301 (130837);

are being filed on the same date as the present application, the contents of which are incorporated herein by reference in their entireties.

### BACKGROUND OF THE INVENTION

1. Field of the Invention

The subject matter disclosed herein relates to sensing information associated with switching devices and, more specifically, to sensing this information according to a wide range of operating conditions.

2. Brief Description of the Related Art

Different types of switching devices (e.g., electrical contacts, switches, and so forth) are used in various environments. For example, a power generation plant uses a large number of electrical contacts (e.g., switches and relays). The electrical contacts in a power generation plant can be used to control a wide variety of equipment such as motors, pumps, solenoids and lights. A control system needs to monitor the electrical contacts within the power plant to determine their status in order to ensure that certain functions associated with the process are being performed. In particular, the control system determines whether the electrical contacts are on or off, or whether there is a fault near the contacts such as open field wires or shorted field wires that affect the ability of the contacts to perform their intended function.

One approach that a control system uses to monitor the status of the electrical contacts is to send an electrical voltage (e.g., a direct current voltage (DC) or an alternating current (AC) voltage) to the contacts in the field and determine whether this voltage can be detected. The voltage, which is provided to the electrical contacts for detection, is known as a wetting voltage. If the wetting voltage levels are high, galvanic isolation in the circuits is used as a safety measure while detecting the existence of voltage. Detecting the voltage is an indication that the electrical contact is on or off. A wetting current is associated with the wetting voltage.

Various problems have existed with previous approaches in monitoring contacts and other types of switching devices. For example, the contacts need to be isolated from the control system, or damage to the control system may occur. Also, the control system may need to handle a wide variety of different voltages, but previous devices could only handle voltages within narrow ranges. Previous devices have also been inflexible in the sense that they cannot be easily changed or modified without circuit changes involving setting jumpers and/or adjusting resistors or other components to account for changes in the operating environment or conditions, or received voltages. All of these problems have resulted in general dissatisfaction with previous approaches due to the need to supply many variations of the same circuit function with each set to a particular voltage and/or current.

### BRIEF DESCRIPTION OF THE INVENTION

The approaches described herein provide a universal discrete input stage that is capable of sensing a variety of direct current (DC) or alternating current (AC) inputs and sensing current flows for NAMUR protocol compliant signals that are defined at a first noticed location. NAMUR is a European users group in process and chemical industry measurement and control technology. In one aspect, stepped attenuators are deployed and analog-to-digital (A/D) converters are used for voltage sensing. The A/D converter may be part of a mixed signal application specific integrated circuit (ASIC) or an embedded microcontroller.

In many of these embodiments, a voltage from a switching device across a plurality of attenuation paths is received. Each of the attenuation paths provides a different attenuation to the voltage from the others. At embedded control logic, at least one of the plurality of attenuation paths is chosen and a sensed voltage is determined according to the at least one attenuation path that is chosen.

In some aspects, the received voltage may be a direct current (DC) voltage, an alternating current (AC) voltage, and a NAMUR standard-compliant signal. The NAMUR signal (e.g., defined by IEC60947-5-6, DIN19234) uses a current loop with the impressed voltage at the input stage having four spans of possible values to indicate an open wire (zero volts with below 0.1 mA), open switch (<1 mA current flow with a low input voltage), closed switch (>2.2 mA current flow for a higher input voltage), and short to power (highest current with supply voltage seen). Other examples are possible.

In other aspects, the embedded control logic includes a device such as a microprocessor or an application specific integrated circuit (ASIC). Other examples are possible.

In some examples, each of the attenuation paths includes at least one resistor. In other examples, power isolation between the embedded circuit and a control system is provided.

In other aspects and at the embedded control logic, a control signal is formed to control a current sink and the current sink is configured to regulate current into the embedded circuit. The control signal based upon a set of pre-programmed instructions. The programmed instructions are received from a control system.

An apparatus for sensing voltage across a switching device includes a plurality of attenuation paths and control logic. The plurality of paths receives a voltage from a switching device and each of the attenuation paths provides a different attenuation to the voltage from the others. The control logic is coupled to the plurality of attenuation paths. The control logic is configured to choose at least one of the plurality of attenuation paths and determine a sensed voltage according to the at least one attenuation path that is chosen.

### BRIEF DESCRIPTION OF THE DRAWINGS

For a more complete understanding of the disclosure, reference should be made to the following detailed description and accompanying drawings wherein:

FIG. 1 comprises a block diagram of a contact input circuit according to various embodiments of the present invention;

FIG. 2 comprises a circuit diagram of a contact input circuit according to various embodiments of the present invention;

FIG. 3 comprises a circuit diagram of a stepped voltage input attenuator according to various embodiments of the present invention;

FIG. 4 comprises a plot of various gains of the various attenuation paths according to various embodiments of the present invention; and

FIG. 5A and FIG. 5B comprise circuit diagrams of a contact input circuit according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION OF THE INVENTION

The approaches described herein provide a universal discrete input stage that is capable of sensing a variety of direct current (DC) or alternating current (AC) inputs and sensing current flows for NAMUR protocol compliant signals. In one aspect, stepped attenuators are deployed and analog-to-digital (A/D) converters are used for voltage sensing. The A/D converter may be part of a mixed signal application specific integrated circuit (ASIC) or an embedded microcontroller.

In one advantage of the present approaches, fewer devices are needed to support terminal boards and packs. The present approaches allow for combinations of signals into a discrete input device. The present approaches additionally allow for changes in signal types without changes to discrete input hardware by reconfiguring an input channel.

In some aspects, discrete (binary) inputs are received in many voltage and current ranges. For example, a 12V DC dry contact input with a voltage decision; 24V DC dry contact input with a voltage decision; a 48V DC dry contact input with a voltage decision; a 125V DC dry contact input with a voltage decision; a 24V AC dry contact input with a voltage decision and timing to allow for cyclical input when switch is closed; a 120V AC dry contact input with a voltage decision and timing to allow for cyclical input when switch is closed; a 24V DC wetted contact input having a current flowing with decision based on current level (NAMUR style) to allow for open wire and short detection; a 125V DC wetted contact input having a current flowing with decision based on current level to allow for open wire and short detection may be received.

Each input span covers a range of typical voltages (e.g., approximately 20% or more) with the optional wetting current being selectable over the range of approximately 2 to 10 mA (or potentially more). If NAMUR protocol compliant inputs are used, they use the amount of current to show if a channel is seeing an open wire (no current), open switch (low current), closed switch (medium current), or short (maximum current where the input channel must limit the current). The NAMUR protocol under IEC60947-5-6 specifies the current to be less than 1 mA with the switch open and above 2.2 mA when the switch is closed. By having a controlled current sink circuit, the input circuit may be set for NAMUR operation with a current limit typically at 4 mA. Sensing of the current through the sink circuit allows detection of below 1 or above 2.2 mA, with the 4 mA setting allowing for limiting power dissipation in the event of a short to the supply.

The contact input circuit (sometimes referred to as an input channel herein) includes several portions. Additionally, a control system that uses the channel information as well as configures the channel is provided and couples to the contact input circuit. Communications path isolation is provided, allowing the channel to float electrically with respect to the control system.

A terminal block for wiring to the input channel is also provided. External switch with excitation source voltage and optional series and parallel resistors to provide for NAMUR and open/short detection can be used. A current sink for regulating current into the input channel, where when enabled limits the current to up to a fixed value is provided. The limit value may be adjustable by the channel to allow for settings that are received from the control system.

The current sensing may be either separate or combined with the current sink. If separate, the sense path may be switched open to not interfere with the current sink. If combined, the current sink provides a limit on the current as a safety precaution if the channel has a component failure or is mis-programmed (e.g., wrong input style that might be due to an incorrect customer wiring to the terminal block).

The present approaches provide input sensing and analog-to-digital (A/D) conversion, as a finite state machine within ASIC logic or as a microcontroller performing a software routine. This functional circuitry reacts to control system commands, monitors and times the input signal changes, and responds with the channel state when requested. Power isolation for the channel is provided, due to the floating nature of the circuitry.

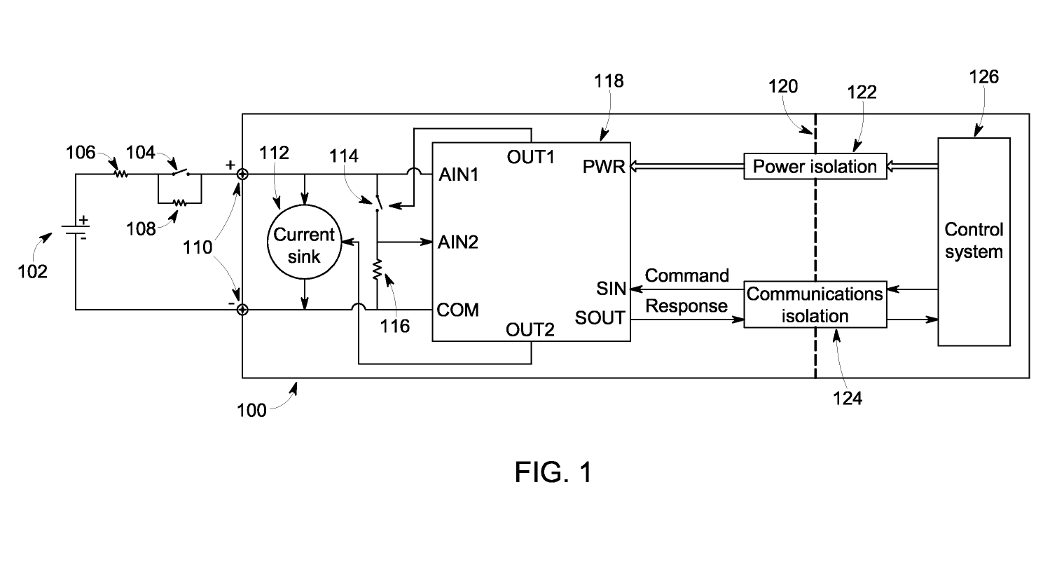

Referring now to the figures and in particular to FIG. 1, a block diagram of a contact input circuit 100 is illustrated in accordance with various approaches. The contact input circuit 100 includes one or more inputs 110, comprising positive and negative input terminals (IN+ and IN−) in this example, an input voltage sensing and digitization module 118, a communication isolation circuit 124, a current sink circuit 112, and an optional power isolation circuit 122. The contact input circuit 100 is configured such that it can provide information about a signal existing on the inputs 110 across an isolation barrier 120 to a control system 126 for processing thereof. The control system 126 may include any combination of processing devices that execute programmed computer software and that are capable of analyzing information received from the contact input circuit 100.

The isolation barrier 120 may represent galvanic separation such that the two sides of the isolation barrier (i.e., the input 110 side and the control system 126 side) are electrically insulated from one another to provide galvanic isolation. The isolation barrier 120 provides protection for the control system 126 from electrical characteristics and abnormalities existing on the input 110 side of the isolation barrier 120 that the control system 126 may simply be incapable of withstanding. For example, the control system 126 may be configured to operate with, for example, approximately 3.3V, 5V, 12V, or 24V power supply and utilize corresponding small signals. However, in one example, the input 110 side of the isolation barrier 120 may be a higher-voltage circuit with operating voltages exceeding approximately 250V, or even approximately 500V. Further, and especially in the instance where switching devices 104 are used in power plant applications or are otherwise geographically spread apart, lighting or other phenomena may create sizeable surges on the inputs 110 exceeding hundreds or thousands of volts, which surges a control system 126 may not be capable of withstanding.

So configured, and in one example setting, the contact input circuit 100 can be utilized with a switching device 104 (e.g., an electro-mechanical switch or other switching means) such that the information provided about the signal existing at the inputs 110 can be utilized to determine various aspects or characteristics of the switching device 104 (e.g., if it is closed, open, shorted, subject to a weak connection, oxidized, etc). In such an example setting, the switching device 104 may be coupled to a power supply 102 or other power source. Various resistances associated with the switching device 104, the power supply 102, or current paths are represented generally by series resistor Rs 106 and parallel resistor Rp 108, which allow for detection of wiring faults per the NAMUR standard, where the open switch voltage and closed switch voltages and input currents are different from an open wire input or a short to the supply 102.

Although only a switching device application is described here, the contact input circuit 100 can be utilized in many various application settings to provide information about signals existing at the inputs 110 to the contact input circuit 100.

By at least one approach, the contact input circuit 100 may be further equipped with the current sink circuit 112. By this, the contact input circuit 100 may be configured to provide, for example, a wetting current across the switching device 104. The wetting current can be advantageously used to prevent and/or break through surface film resistance in the switching device 104, such as a layer of oxidation, which can otherwise cause the switching device 104 to remain electrically open even when it may be mechanically closed. Further applications include providing a sealing current or fritt current as may be utilized in telecommunications and providing current limiting for NAMUR style input devices. Typically, the wetting current is between 1 and 10 mA, though other values are possible.

By at least another approach, the communication isolation circuit 124 can provide communications from the control system 126 to the contact input circuit 100. For example, these communications may be commands to control the current sink circuit 112 according to various requirements and/or sensed aspects of the input signal. Lastly, in another approach, the contact input circuit 100 may include a power isolation circuit 122 that is configured to provide power to the contact input circuit 100 through power transfer across the isolation barrier 120 (e.g., through the use of a transformer or by other known power transfer techniques).

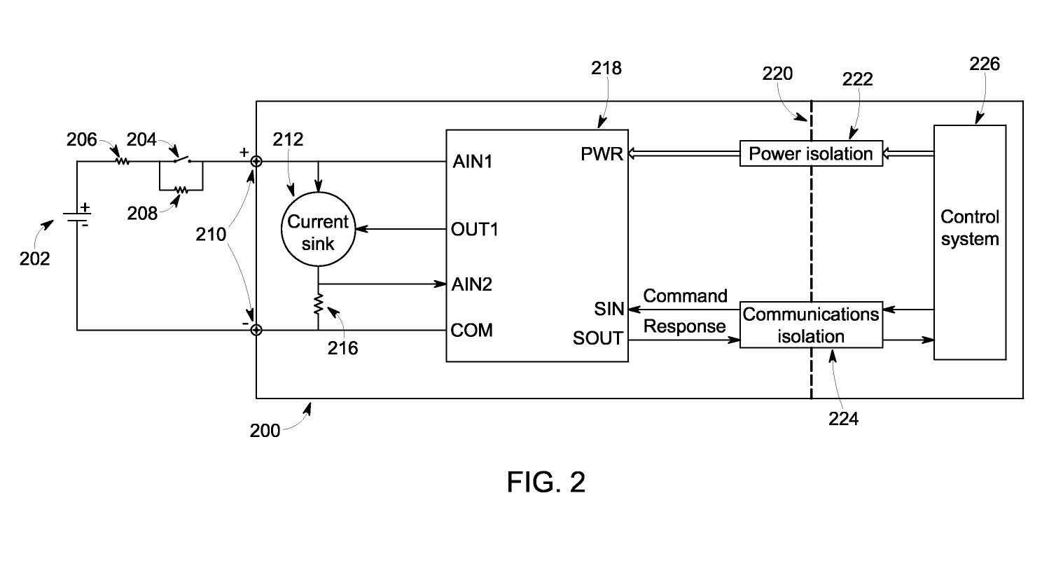

FIG. 2 illustrates the same components as FIG. 1 in a similar configuration (including power supply 202, switching device 204, series and parallel resistors 206 and 208, input contacts 210, current sink 212, input voltage and sensing and digitization module 218, and power isolation circuit 222 and communications isolation circuit 224 configured to allow the contact input circuit 200 to communicate with a control system 226 across an isolation barrier.

The primary difference between FIG. 1 and FIG. 2 is with respect to the location of the current sense burden resistor 116, 216 in relation to the current sink circuits 112, 212. In FIG. 1, the current sense burden resistor 116 is placed in parallel to the current sink circuit 112. Input voltage is placed across the current sense burden resistor 116 and the input voltage sensing and digitization module 118 then reads the voltage generated across the current sense burden resistor 116. Because the current sense burden resistor 116 may interfere with the wetting current provided by current sink circuit 112, a switching device, such as analog switch 114, may be provided and controlled by the input voltage sensing and digitization module 118 to selectively enable and disable the current sense burden resistor 116 to selectively read the input voltage.

In another approach shown in FIG. 2, the current sense burden resistor 216 is placed in series with the current sink 212. In such a configuration, the current sense burden resistor 216 adds a safety feature to the current sink 212 in that it may operate to limit the wetting current flowing therethrough in the instance of malfunction or mis-wiring.

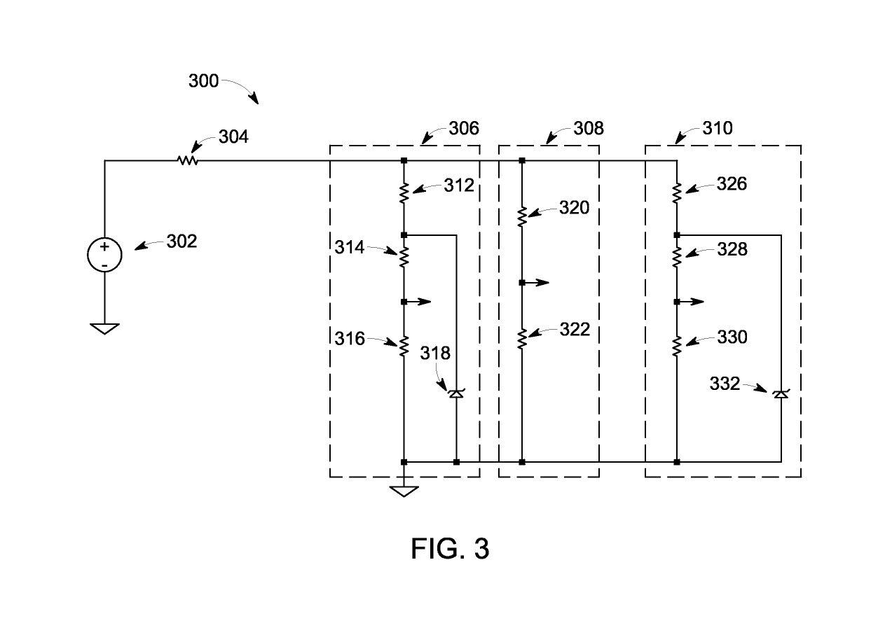

With reference now to FIG. 3, a stepped voltage input attenuator 300 is described. The stepped voltage input attenuator 300 serves to reduce the voltage provided to the input voltage sensing and digitization module 118, 218 to a range that is within the operating voltage of the digitization module 118, 218 (e.g., 0-5V). As the input to the contact input circuit 100, 200 can range greatly from 0V to as high as 500V, this voltage must be attenuated prior to being fed to the voltage sensing and digitization module 118, 218. Conventional input attenuators may comprise a set circuit configuration (e.g., a resistor voltage divider) that provides a single voltage output relative to the entire input voltage range. However, the stepped voltage input attenuator 300 is configured to output multiple different attenuated voltages with varying gains to better accommodate sensing of the wide range of input voltages.

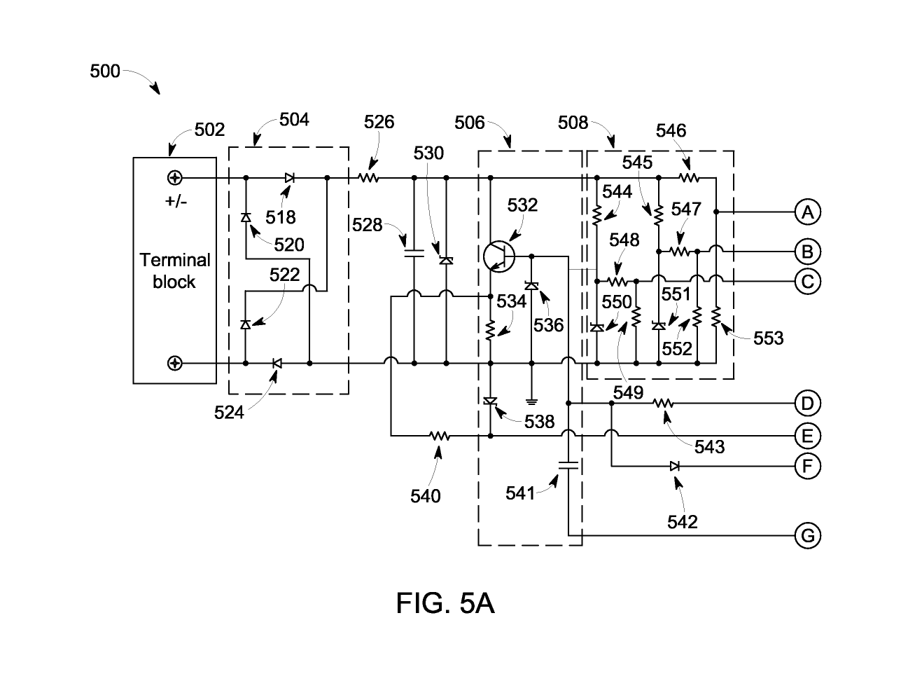

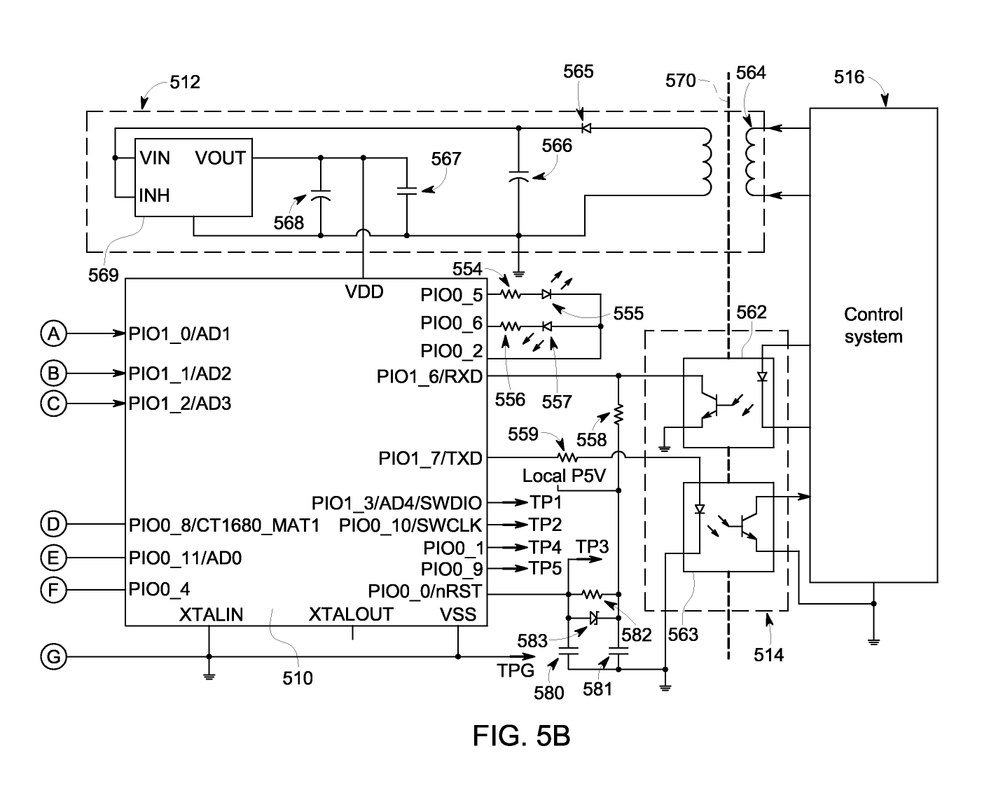

FIG. 3 includes a voltage source 302, which is a simulated voltage as may be present on the inputs 110, 210 of the contact input circuit 100, 200 of FIGS. 1 and 2, as well as input resistor 304, which correspond to input resistor 526 of FIGS. 5A and 5B. The stepped voltage input attenuator 300 includes three different attenuation paths 306, 308, 310, each corresponding to a different gain and maximum input voltage. Each attenuation path comprises a resistor voltage divider circuit, and may include a voltage clamp zener diode to prevent the output from exceeding an allowable input into the voltage sensing and digitization module 118, 218.

Attenuation path 306 may correspond to, for example, a maximum voltage of 48 volts (with a certain tolerance by some approaches, for example, including about 10%). Resistors 312, 314, and 316 are selected so that a voltage at or near the higher end of the allowable input into the voltage sensing and digitization module 118, 218 (for example, 5V) is achieved when the input voltage is at around 48V. This creates a higher gain than the other attenuation paths 308 and 310. Zener clamp diode 318 is provided to ensure that the output of this first attenuation path 306 (existing between resistors 314 and 316) does not exceed the maximum output (e.g., 5V) even when the input voltage exceeds the 48V point.

Attenuation path 310 may correspond to, for example, a maximum voltage of 150V. Resistors 326, 328, and 330 are selected so that a voltage at or near the higher end of the allowable input into the voltage sensing and digitization module 118, 218 (for example, 5V) is achieved when the input voltage is at around 150V. This creates a lower gain than attenuation path 306, but higher than attenuation path 310. Zener clamp diode 332 is provided to ensure that the output of this second attenuation path 310 (existing between resistors 328 and 330) does not exceed the maximum output (e.g., 5V) even when the input voltage exceeds the 150V point.

Finally, attenuation path 308 may correspond to, for example, a maximum voltage of 250V. Resistors 320 and 322 are selected so that a voltage at or near the higher end of the allowable input into the voltage sensing and digitization module 118, 218 (for example, 5V) is achieved when the input voltage is at around 250V. This creates a lower gain than attenuation paths 306 and 310. This attenuation path may not require a zener clamp diode as the input voltage may not exceed a maximum input 250V in this example and thus, the output (between resistors 320 and 322) will not exceed the maximum for the voltage sensing and digitization module 118, 218 (though other maximum inputs are possible by other approaches, including but not limited to 500V, wherein a 250V maximum attenuation path 308 would preferably include a zener clamp diode). It should be understood that these teachings can be expanded to any number of attenuation paths set to any number of different voltage maximums and gains, and the examples provided herein are in no way meant to be limiting.

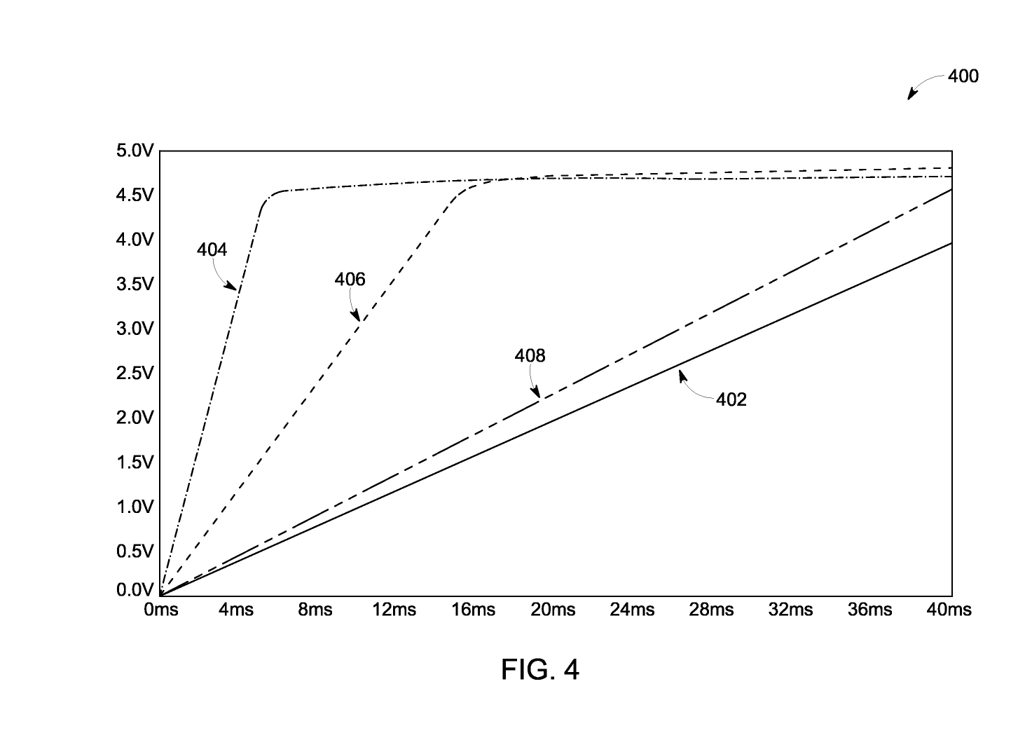

Turning to FIG. 4, the various gains of the various attenuation paths 306, 308, 310 of FIG. 3 are illustrated in graph 400 by one example. The x-axis represents time as a voltage on the input (i.e., simulated voltage 302 in FIG. 3) is swept linearly from 0V to 250V (and thus indirectly represents input voltage). The voltage sweep on the input is illustrated by line 402 (also referred to as input voltage 402). The y-axis represents the output voltage that is fed to the voltage sensing and digitization module 118, 218. Curve 404 represents the output of the first attenuation path 306 (with an example maximum input voltage of 48V), curve 406 represents the output of the second attenuation path 310 (with an example maximum input voltage of 150V), and curve 408 represents the output of the third attenuation path 308 (with an example maximum input voltage of 250V). As can be seen from the graph 400, as the input voltage 402 remains lower (e.g., from 0-48V), all three attenuation paths 306, 308, 310 are active and will provide usable output readings to the voltage sensing and digitization module 118, 218 (corresponding to the sloped portions of each curve 404, 406, 408). As the input voltage 402 increases beyond the example 48V, the first attenuation path 306 will become clamped near 5V, and will be otherwise unusable to provide an accurate reading corresponding to the input voltage. However, the second and third attenuation paths 310, 308, will remain active and usable for readings corresponding to the input voltage. As the input voltage increases more and surpasses the example 150V maximum of the second attenuation path 310, the second attenuation path 310 will clamp to near 5V, leaving the third attenuation path 308 as the only active path.

By this, a varying degree of precision can be achieved according to the input voltage range. For example, and with continuing reference to FIG. 4, if the input voltage 402 was very low, for example, near 12V, the output voltage from attenuation path 308 (with a maximum of approximately 250V and representing the entire input range in this example) would output a very small voltage. However, the second attenuation path 310 would output a larger output voltage, while the first attenuation path 306 would output the largest output voltage as it is the most sensitive. This increased sensitivity to lower input voltages allows for enhanced resolution when measuring these lower input voltage (that is, up until the respective attenuation path maxes out). Allowing for this increased resolution allows for less sophisticated or accurate digital-to-analog converters to be used at the input to the voltage sensing and digitization module 118, 218. Further, the redundant measurements created by the varying attenuation paths 306, 308, 310 allow for the voltage sensing and digitization module 118, 218 to check sensed values against each other to ensure that the device is operating properly.

Referring now to FIG. 5A and FIG. 5B, a circuit diagram for a contact input circuit 500 incorporating the features discussed above is disclosed in accordance with one approach. Much like the block diagrams of FIGS. 1 and 2, the contact input circuit 500 includes, input contacts 502, the current sink circuit 506, an input voltage sensing and digitizing module (represented here in part as processing device 510 with an example of a LPC1111 from N×P containing A/D, timing, communications, memory, and a 32 bit processor), communications isolation circuit 514 configured to communicate with control system 516 across an isolation barrier 570, and an optional power isolation circuit 512. The above described stepped voltage attenuator is also included as a voltage attenuator circuit 508, with its outputs being fed into analog-to-digital (ADC) inputs of the processing device 510.

Voltage enters the contact input circuit 500 through optional diode bridge 504 (to allow for use with alternating current (AC) as well as protecting against reverse voltages such as from incorrect user wiring to the input contacts (or terminals) 502) and an input resistor 526. The diode bridge is assembled of diodes 518, 520, 522, and 524 configured in a standard diode bridge 504. The input signal is then low pass filtered with filtering capacitor 528, which acts to create a DC voltage from the diode bridge 504 output when AC current is used. Protection diode 530 is also placed across the inputs and operates to ensure that the contact input circuit 500 is not damaged if the voltage inputs to the contact input circuit 500 are excessively high as the case of over-voltages such as surges.

The input signal continues into the voltage attenuator circuit 508 as was described in FIG. 3, and includes resistors 544, 545, 546, 547, 548, 549, 552, and 553 and zener diodes 550 and 551. As described above, the voltage attenuator circuit 508 outputs a plurality of attenuated voltages with varying gains and maximums, with three outputs being illustrated here. The multiple attenuated outputs are sent to multiple analog-to-digital converter (ADC) inputs of the processing device 510.

By one approach, the processing device 510 is configured to measure the voltage of the signals received from the voltage attenuator circuit 508. This may be achieved by known analog-to-digital conversion techniques, or other known voltage measurement techniques, that may be internal or external to the processing device 510. By measuring these attenuated voltages, the processing device 510 then knows the voltage that exists at the contacts 502 to the contact input circuit 500. The processing device 510 may be able to relate the attenuated voltages to the actual voltage at the contacts 502 through the use of a lookup table (e.g., relating the values of the measured attenuated voltage to the input voltage) or through a simple calculation corresponding to the relation between the attenuated and actual voltages.

The processing device 510 may be further configured with one or more additional inputs that are individually or collectively configured to receive communications from external sources. For example, the processing device 510 may be able to receive commands and/or data from the control system 516 through communication isolation circuit 514 via optocoupler 562 across isolation barrier 570 to an input. This input (or another input) may also be configured to receive communications from a local source (i.e., not across the isolation barrier 570) from, for example, a universal asynchronous receiver transmitter (UART), universal serial bus (USB), or other communication port that may communicate with diagnostic and/or programming equipment, a computer, other contact input circuits 500. Further still, the processing device 510 may be configured with one or more outputs that can relay commands and/or data to an external device, such as the control system 516. For example, the processing device 510 may output the output data signal through a resistor 559 and through communication isolation circuit 514 via optocoupler 563 across the isolation barrier 570 to the control system 516. The output signal may be provided to other devices as well as needed.

The processing device 510, by other approaches, may also include LED diodes 555 and 557, which are selectively illuminated through resistors 554 and 556 to provide visual indications regarding the contact input circuit 500, such as operating statuses as well as communication statuses. Additionally still, by some approaches, the processing device 510 may also include a watchdog circuit to detect and recover from computing malfunctions. Resistor 582, capacitors 580 and 581, and Schottky diode 583 are used to provide the timing for the power up reset circuit.

In one approach, the processing device 510 is further configured to control the wetting current produced by the current sink 506. With the knowledge of the incoming voltage sensed from the outputs of the attenuator circuit 508, the processing device 510 can vary the wetting current that is driven by the current sink 506 according to the needs of the present conditions or voltage across the input contacts 502. For example, if a low voltage exists across the input contacts 502 (e.g., approximately 12V or 24V), a higher wetting current may be required to ensure enough power is provided across the switching device 104, 204 contacts to ensure their health. However, if that same higher current were used with a higher voltage, such as 250V or 500V, that higher current would result in a much higher power than is needed across the contacts. This would also result in the need for unnecessarily large components capable of sinking the extra power that would be generated by the higher current combined with the higher voltage. Therefore, in the contact input circuit 500 as described herein, which is capable of operating with a wide range of switch voltages, it is beneficial to vary the current through the current sink 506 to minimize unnecessary power dissipation and corresponding component selection. Accordingly, the processing device 510 may be configured to select an optimized wetting current for the given input voltage and further configured to control the current sink circuit 506 according to its selection. By one approach, the processing device 510 outputs a pulse train that is then filtered to be useable by the current sink circuit 506.

The current sink 506 includes a transistor 532 (shown here as an NPN transistor, though other transistor types may be equally as suitable) with its collector connected to the high voltage input and its emitter connected through a resistor 534 to ground. This path provides a wetting current across the input contacts 502 and thus across the switching device 104, 204. By one approach, the current sink circuit 506 receives a pulse train from the processing device 510 into input resistor 543. The pulse train is then low pass filtered by a zener diode 536 and a capacitor 541 in parallel between the base of the transistor 532 and ground. By this, the low pass filter will establish a DC voltage at the base of the transistor 532 commensurate with the duty cycle of the wetting current pulse train from the processing device 510. This DC voltage will resultantly set the wetting current through the transistor 532. Thus, the wetting current can be varied as needed via local control directly within the same input contact circuit 500.

By certain approaches, the processing device may also receive a voltage sensed across protection resistor 540 that indicates the current actually passing through the current sink 506. The resistor 540 is in parallel with resistor 534 and a zener diode 538 to ensure the sensed voltage does not exceed the input limit of the processing device 510. Additionally, in an instance the processing device may need to cut the wetting current through current sink 506, a diode 542 is provided to an output pin of the processing device that will be able to quickly sink the charge that is stored on the low pass filter capacitor 541 to ensure a detection of a high current (such as from a circuit fault) or high input voltage does not destroy the transistor 532 in the time it takes for capacitor 541 to discharge with the pulse train set to a minimum value.

Optionally, the processing device 510 and other components of the input contact circuit 500 may be powered from power sourced from the control system 516 (or another source across the isolation barrier 570 using power isolation circuit 512. In one example, a transformer 564 is provided with current in its primary side winding from the control system 516, which power is then transferred across the isolation barrier 570 to the secondary winding of the transformer 564. By one approach, and in an attempt to minimize a foot print as well as cost, the transformer 564 may be a planar transformer comprised of two sets of loops (i.e., the primary and secondary windings) within a circuit board. Current from the secondary winding of the transformer 564 travels through rectifying diode 565 and across filtering capacitor 566, which operates to provide a filtered input into voltage regulator 569. Voltage regulator 569 outputs a positive voltage supply for the contact input circuit 500, which can be further filtered by filtering capacitors 567 and 568. This operating voltage can then be used by the processing device 510 as well as other components requiring operating voltages.

It will be appreciated that the various examples described herein use various components (e.g., resistors and capacitors) that have certain values. Example values may be shown in the figures for some of these components. However, if not shown, these values will be understood or easily obtainable by those skilled in the art and, consequently, are not mentioned here.

It will be appreciated by those skilled in the art that modifications to the foregoing embodiments may be made in various aspects. Other variations clearly would also work, and are within the scope and spirit of the invention. The present invention is set forth with particularity in the appended claims. It is deemed that the spirit and scope of that invention encompasses such modifications and alterations to the embodiments herein as would be apparent to one of ordinary skill in the art and familiar with the teachings of the present application.

What is claimed is:

1. A method for sensing voltage across a switching device, the method comprising:
receiving a voltage from a switching device across a plurality of attenuation paths, each of the plurality of attenuation paths providing a different attenuation to the voltage from the others;
at embedded control logic:
choosing at least one of the plurality of attenuation paths and determining a sensed voltage according to the at least one attenuation path that is chosen.

2. The method of claim 1 wherein the received voltage is at least one of a direct current (DC) voltage, an alternating current (AC) voltage, and a NAMUR standard-compliant signal.

3. The method of claim 1 wherein the embedded control logic comprises a device selected from the group consisting of: a microprocessor and an application specific integrated circuit (ASIC).

4. The method of claim 1 wherein each of the attenuation paths comprise at least one resistor.

5. The method of claim 1 further comprising providing power isolation between the embedded control logic and a control system.

6. The method of claim 1 further comprising, at the embedded control logic, forming a control signal to control a current sink, the current sink configured to regulate current into the embedded circuit, the control signal based upon a set of pre-programmed instructions.

7. The method of claim 1 further comprising receiving programmed instructions from a control system.

8. An apparatus for sensing voltage across a switching device, the apparatus comprising:
a plurality of attenuation paths, the plurality of attenuation paths receiving a voltage from a switching device and each of the plurality of attenuation paths providing a different attenuation to the voltage from the others;
control logic, the control logic being coupled to the plurality of attenuation paths, the control logic configured to choose at least one of the plurality of attenuation paths and determining a sensed voltage according to the at least one attenuation path that is chosen.

9. The apparatus of claim 8 wherein the received voltage is at least one of a direct current (DC) voltage, an alternating current (AC) voltage, and a NAMUR standard-compliant signal.

10. The apparatus of claim 8 wherein the embedded control logic comprises a device selected from the group consisting of: a microprocessor and an application specific integrated circuit (ASIC).

11. The apparatus of claim 8 wherein each of the attenuation paths comprise at least one resistor.

12. The apparatus of claim 8 wherein power isolation is provided between the embedded control logic and a control system.

13. The apparatus of claim 8 wherein the embedded control logic is configured to form a control signal to control a current sink, the current sink configured to regulate current into the embedded circuit, the control signal based upon a set of pre-programmed instructions.

14. The apparatus of claim 8 wherein the embedded control logic is further configured to receive programmed instructions from a control system.
